(19) United States
(12) Patent Application Publication
(10) Pub. No.: US 2007/0205805 A1
(43) Pub. Date: Sep. 6, 2007

(54) Electrical system including driver that provides a first drive strength and a second drive strength

(76) Inventors: Oliver Kiehl, Charlotte, VT (US); William Shen, Los Altos, CA (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/367,624

(22) Filed: Mar. 3, 2006

(51) Int. Cl. H03K 19/0175

(52) U.S. Cl. 326/82

(57) ABSTRACT

An electrical system including a signal line and a driver. The signal line is terminated via a passive component. The driver is configured to receive an input signal and provide an output signal via the signal line. The driver is configured to provide an output logic level in the output signal at a first drive strength and to switch and provide the output logic level in the output signal at a second drive strength. The first drive strength is greater than the second drive strength.

### BACKGROUND

Typically, an electrical system includes a number of circuits that communicate with one another to perform system applications. The circuits can be on the same integrated circuit chip or on separate integrated circuit chips. Chip speeds continue to increase and the amount of data communicated between circuits continues to increase to meet the demands of system applications. As the volume of digital data communicated between circuits continues to increase, higher bandwidth communication links are needed to prevent data communication bottlenecks between circuits and/or chips.

Often, an electrical system includes a controller, such as a micro-processor, and one or more memory modules. The memory modules can be dual in-line memory modules (DIMMs) that include random access memory (RAM) chips. The RAM chips can be any suitable type of RAM, such as dynamic RAM (DRAM) and double data rate DRAM (DDR-DRAM), including double data rate synchronous DRAM (DDR-SDRAM). Also, the RAM chips can be any suitable generation of DDR-SDRAM, such as first, second, and third generation DDR-SDRAM. The controller communicates with the memory modules to store data and read stored data.

The DIMM modules can be registered DIMM (RDIMM) or fully buffered DIMM (FB-DIMM). An RDIMM includes a registered driver circuit that provides signals, such as address and command signals, to onboard DRAM. An FB-DIMM includes an advanced memory buffer (AMB) that provides signals to the onboard DRAM. In either DIMM, the signals are provided to onboard DRAM via a communications link, such as a terminated bus.

Typically, a terminated bus includes signal lines that are terminated via a resistor. Often, high speed signals are transmitted and received via the terminated bus. To achieve high signal integrity, large voltage swings are used in the high speed signals on the terminated bus. However, large signal swings cause high power consumption in the termination resistors of the terminated bus.

For these and other reasons there is a need for the present invention.

### SUMMARY

One aspect of the present invention provides an electrical system including a signal line and a driver. The signal line is terminated via a passive component. The driver is configured to receive an input signal and provide an output signal via the signal line. The driver is configured to provide an output logic level in the output signal at a first drive strength and to switch and provide the output logic level in the output signal at a second drive strength. The first drive strength is greater than the second drive strength.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of an electrical system according to the present invention.

FIG. 2 is a diagram illustrating one embodiment of an RDIMM according to the present invention.

FIG. 3 is a block diagram illustrating one embodiment of an FB-DIMM according to the present invention.

FIG. 4 is a diagram illustrating one embodiment of an electrical system that includes a driver circuit, a DRAM, and a termination resistor.

FIG. 5 is a diagram illustrating one embodiment of a driver circuit.

FIG. 6 is a diagram illustrating one embodiment of an output circuit.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

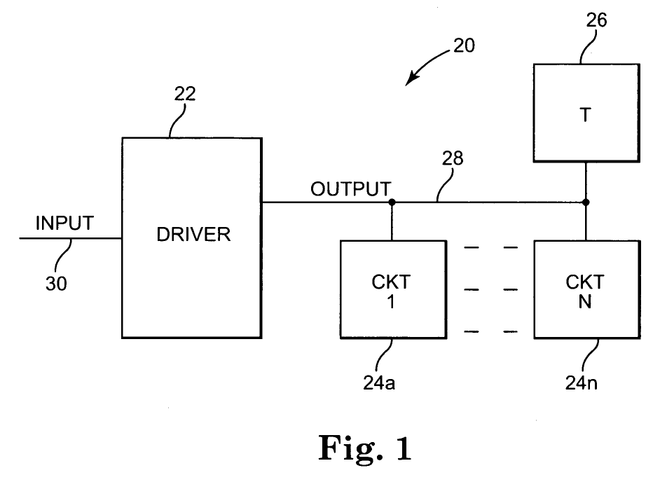

FIG. 1 is a diagram illustrating one embodiment of an electrical system 20 according to the present invention. Electrical system 20 includes a driver circuit 22, system circuits 24a-24n, and a termination circuit 26. Driver circuit 22 is electrically coupled to each of the system circuits 24a-24n and to termination circuit 26 via communications bus 28. Termination circuit 26 includes one or more passive components and communications bus 28 includes one or more signal lines that are terminated via the passive components in termination circuit 26. In one aspect communications bus 28 is a terminated communications bus 28.

In one embodiment, driver circuit 22 includes multiple output circuits and communications bus 28 includes multiple signal lines, wherein each of the multiple output circuits provides an output signal via one of the multiple signal lines. In one embodiment, driver circuit 22 includes one output circuit and communications bus 28 includes one signal line, wherein the one output circuit provides an output signal via the one signal line.

Driver circuit 22 receives input signal INPUT at 30 and provides a corresponding output signal OUTPUT at 28 to system circuits 24a-24n via terminated communications bus 28. Driver circuit 22 provides an output logic level in output signal OUTPUT at 28 at a first drive strength. Driver circuit 22 then switches and provides the output logic level in the output signal OUTPUT at 28 at a second drive strength, wherein the first drive strength is greater than the second drive strength. Switching to the second drive strength saves power in electrical system 20. In one embodiment, the first drive strength is substantially ten times greater than the second drive strength.

System circuits 24a-24n can be any suitable electrical circuits in electrical system 20. In one embodiment, system circuits 24a-24n are selected and deselected via a select signal. In one embodiment, driver circuit 22 switches and provides the output logic level in the output signal OUTPUT at 28 at the second drive strength in response to and based on de-selection of the system circuits 24a-24n via the select signal.

In one embodiment, driver circuit 22 switches and provides the output logic level in the output signal OUTPUT at 28 at the second drive strength based on the input signal INPUT at 30. In one embodiment, driver circuit 22 switches and provides the output logic level in the output signal OUTPUT at 28 at the second drive strength based on the input signal INPUT at 30 remaining at one input logic level, i.e., not transitioning. In one embodiment, driver circuit 22 switches and provides the output logic level in the output signal OUTPUT at 28 at the second drive strength based on a time period from a transition of the input signal INPUT at 30, wherein the time period can be any suitable time period, such as a fraction of a clock period or one or more clock periods. In one embodiment, driver circuit 22 switches and provides the output logic level in the output signal OUTPUT at 28 at the second drive strength based on a combination of reaching a signal level of the output signal OUTPUT at 28 and the time from a transition of the input signal INPUT at 30. In one embodiment, driver circuit 22 switches and provides the output logic level in the output signal OUTPUT at 28 at the second drive strength based on reaching the signal level in the output signal OUTPUT at 28.

FIG. 2 is a diagram illustrating one embodiment of an RDIMM 40 according to the present invention. RDIMM 40 includes a registered driver circuit 42, first DDR-DRAM circuits 44a-44n, second DDR-DRAM circuits 44n+1-44x, first termination circuit 46, and second termination circuit 48. In other embodiments, RDIMM 40 includes any suitable number of registered driver circuits 42. In one embodiment, DDR-DRAM circuits 44a-44x are third generation DDR-SDRAM (DDRIII-SDRAM). In other embodiments, RDIMM 40 includes any suitable type of memory circuits.

RDIMM 40 includes DDR-DRAM circuits 44a-44x. In one embodiment, RDIMM 40 includes 36 DDR-DRAM circuits 44a-44x. In one embodiment, RDIMM 40 includes 20 first DDR-DRAM circuits 44a-44n and 16 second DDR-DRAM circuits 44n+1-44x. In one embodiment, RDIMM 40 is a 2 rank by 4 data bit RDIMM that includes 36 DDR-DRAM circuits 44a-44x.In one embodiment, RDIMM 40 includes 18 DDR-DRAM circuits 44a-44x.In one embodiment, RDIMM 40 is a 2 rank by 8 data bit RDIMM that includes 18 DDR-DRAM circuits 44a-44x. In other embodiments, RDIMM 40 includes any suitable number of DDR-DRAM circuits 44a-44x.

Registered driver circuit 42 is electrically coupled to each of the first DDR-DRAM circuits 44a-44n and to first termination circuit 46 via first communications bus 50. Also, registered driver circuit 42 is electrically coupled to each of the second DDR-DRAM circuits 44n+1-44x and to second termination circuit 48 via second communications bus 52. First termination circuit 46 includes multiple resistors and first communications bus 50 includes multiple signal lines. Each of the signal lines in first communications bus 50 is terminated via one of the resistors in first termination circuit 46. Second termination circuit 48 includes multiple resistors and second communications bus 52 includes multiple signal lines. Each of the signal lines in second communications bus 52 is terminated via one of the resistors in second termination circuit 48. In one aspect, first communications bus 50 is a terminated communications bus and second communications bus 52 is a terminated communications bus. In one aspect, first communications bus 50 is a fly-by communications bus and second communications bus 52 is a fly-by communications bus.

Registered driver circuit 42 includes two sets of output circuits. One set of output circuits provides output signals via first communications bus 50 to first DDR-DRAM circuits 44a-44n. The other set of output circuits provides output signals via second communications bus 52 to second DDR-DRAM circuits 44n+1-44x. Each of the output circuits in the one set of output circuits is electrically coupled to one of the signal lines in first communications bus 50. Each of the output circuits in the other set of output circuits is electrically coupled to one of the signal lines in second communications bus 50.

RDIMM 40 is written and read based on input signals INPUT at 54. Registered driver circuit 42 receives input signals INPUT at 54 via system communications bus 54. Input signals INPUT at 54 include address signals, command signals, a clock signal, and one or more select signals. RDIMM 40 and DDR-DRAM circuits 44a-44x are selected and deselected via the received select signal(s).

Registered driver circuit 42 registers the received address and command signals via the clock signal and provides registered address and command signals in output signals OUTPUT1 at 50 and OUTPUT2 at 52. Registered driver circuit 42 outputs address and command signals in output signals OUTPUT1 at 50 to the DDR-DRAM circuits 44a-44n via first communications bus 50 and in output signals OUTPUT2 at 52 to the DDR-DRAM circuits 44n+1-44x via second communications bus 52. Each of the output signals in OUTPUT1 at 50 and OUTPUT2 at 52 corresponds to one of the received address and command signals in input signals INPUT at 54.

In each of the output signals OUTPUT1 at 50 and OUTPUT2 at 52, registered driver circuit 42 outputs a logic level at a first drive strength that is strong enough to switch or maintain receivers in the DDR-DRAM circuits 44a-44x at a corresponding receiver output logic level. Next, based on one or more criteria, registered driver circuit 42 switches to output the logic level at a second drive strength that is strong enough to maintain the receivers in the DDR-DRAM circuits 44a-44x at the same receiver output logic level. The first drive strength is greater than the second drive strength and switching to the second drive strength saves power in RDIMM 40. In one embodiment, the first drive strength is substantially ten times greater than the second drive strength.

Registered driver circuit 42 switches to output the logic level at the second drive strength based on one or more of the following: the input signal, the output signal, and a select signal. In one embodiment, registered driver circuit 42 switches and outputs the logic level at the second drive strength in response to the select signal deselecting RDIMM 40. In one embodiment, registered driver circuit 42 switches and outputs the logic level at the second drive strength based on the input signal remaining at a constant input logic level, i.e., not transitioning. In one embodiment, registered driver circuit 42 switches and outputs the logic level at the second drive strength based on a time period from the last transition of the input signal, wherein the time period can be any suitable time period, such as a fraction of a clock period or one or more clock periods or cycles. In one embodiment, registered driver circuit 42 switches and outputs the logic level at the second drive strength based on a combination of reaching a signal level in the output signal and the time from a transition of the input signal. In one embodiment, registered driver circuit 42 switches and outputs the logic level at the second drive strength based on reaching a signal level in the output signal.

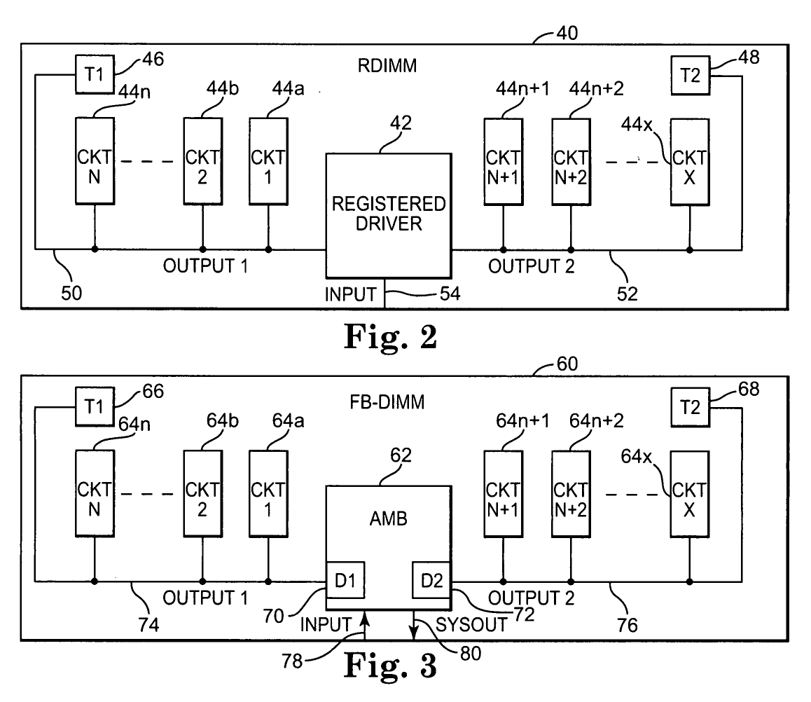

FIG. 3 is a block diagram illustrating one embodiment of an FB-DIMM 60 according to the present invention. FB-DIMM 60 includes an advanced memory buffer (AMB) 62, first DDR-DRAM circuits 64a-64n, second DDR-DRAM circuits 64n+1-64x, first termination circuit 66, and second termination circuit 68. AMB 62 includes a first set of drivers 70 and a second set of drivers 72. In other embodiments, AMB 62 includes any suitable number of sets of drivers. In one embodiment, DDR-DRAM circuits 64a-64x are third generation DDR-SDRAM (DDRIII-SDRAM). In other embodiments, FB-DIMM 60 includes any suitable type of memory circuits.

FB-DIMM 60 includes DDR-DRAM circuits 64a-64x. In one embodiment, FB-DIMM 60 includes 18 DDR-DRAM circuits 64a-64x. In one embodiment, FB-DIMM 60 includes 10 first DDR-DRAM circuits 64a-64n and 8 second DDR-DRAM circuits 64n+1-64x. In one embodiment, FB-DIMM 60 includes 5 first DDR-DRAM circuits 64a-64n and 4 second DDR-DRAM circuits 64n+1-64x on each of two sides of a circuit board. In one embodiment, FB-DIMM 60 includes any suitable number of DDR-DRAM circuits 64a-64x.

AMB 62 and the first set of drivers 70 are electrically coupled to each of the first DDR-DRAM circuits 64a-64n and to first termination circuit 66 via first communications bus 74. Also, AMB 62 and the second set of drivers 72 are electrically coupled to each of the second DDR-DRAM circuits 64n+1-64x and to second termination circuit 68 via second communications bus 76. First termination circuit 66 includes multiple resistors and first communications bus 74 includes multiple signal lines. Each of the signal lines in first communications bus 74 is terminated via one of the resistors in first termination circuit 66. Second termination circuit 68 includes multiple resistors and second communications bus 76 includes multiple signal lines. Each of the signal lines in second communications bus 76 is terminated via one of the resistors in second termination circuit 68. In one aspect, first communications bus 74 is a terminated communications bus and second communications bus 76 is a terminated communications bus. In one aspect, first communications bus 74 is a fly-by communications bus and second communications bus 76 is a fly-by communications bus.

The first set of drivers 70 provide output signals via first communications bus 74 to first DDR-DRAM circuits 64a-64n. The second set of drivers 72 provide output signals via second communications bus 76 to second DDR-DRAM circuits 64n+1-64x. Each of the output circuits in the first set of drivers 70 is electrically coupled to one of the signal lines in first communications bus 74. Each of the output circuits in the second set of drivers 72 is electrically coupled to one of the signal lines in second communications bus 76.

FB-DIMM 60 is written and read based on input signals INPUT received via system input communications bus 78. FB-DIMM 60 outputs system signals SYSOUT via system output communications bus 80. AMB 62 receives input signals INPUT at 78 via system input communications bus 78. Input signals INPUT at 78 include address signals, command signals, clock signals, and one or more select signals. FB-DIMM 60 and DDR-DRAM circuits 64a-64x are selected and deselected via the received select signal(s).

AMB 62 outputs address and command signals in output signals OUTPUT1 at 74 and OUTPUT2 at 76. The first set of drivers 70 output address and command signals in output signals OUTPUT1 at 74 to the DDR-DRAM circuits 64a-64n via first communications bus 74. The second set of drivers 72 output address and command signals in output signals OUTPUT2 at 76 to the DDR-DRAM circuits 64n+1-64x via second communications bus 76. Each of the output signals in OUTPUT1 at 74 and OUTPUT2 at 76 corresponds to one of the received address and command signals in input signals INPUT at 78.

In each of the output signals OUTPUT1 at 74 and OUTPUT2 at 76, a driver in the first set of drivers 70 or the second set of drivers 72 of AMB 62, outputs a logic level at a first drive strength that is strong enough to switch or maintain receivers in the DDR-DRAM circuits 64a-64x at a corresponding receiver output logic level. Next, based on one or more criteria, the driver switches to output the logic level at a second drive strength that is strong enough to maintain the receivers in the DDR-DRAM circuits 64a-64x at the same receiver output logic level. The first drive strength is greater than the second drive strength and switching to the second drive strength saves power in FB-DIMM 60. In one embodiment, the first drive strength is substantially ten times greater than the second drive strength.

Each of the drivers in the first set of drivers 70 and the second set of drivers 72 of AMB 62, switch to output the logic level at the second drive strength based on one or more of the following: the input signal, the output signal, and a select signal. In one embodiment, a driver switches and outputs the logic level at the second drive strength in response to the select signal deselecting FB-DIMM 60. In one embodiment, a driver switches and outputs the logic level at the second drive strength based on the input signal remaining at a constant input logic level, i.e., not transitioning. In one embodiment, a driver switches and outputs the logic level at the second drive strength based on a time period from the last transition of the input signal, wherein the time period can be any suitable time period, such as a fraction of a clock period or one or more clock periods or cycles. In one embodiment, a driver switches and outputs the logic level at the second drive strength based on a combination of reaching a signal level in the output signal and the time from a transition of the input signal. In one embodiment, a driver switches and outputs the logic level at the second drive strength based on reaching a signal level in the output signal.

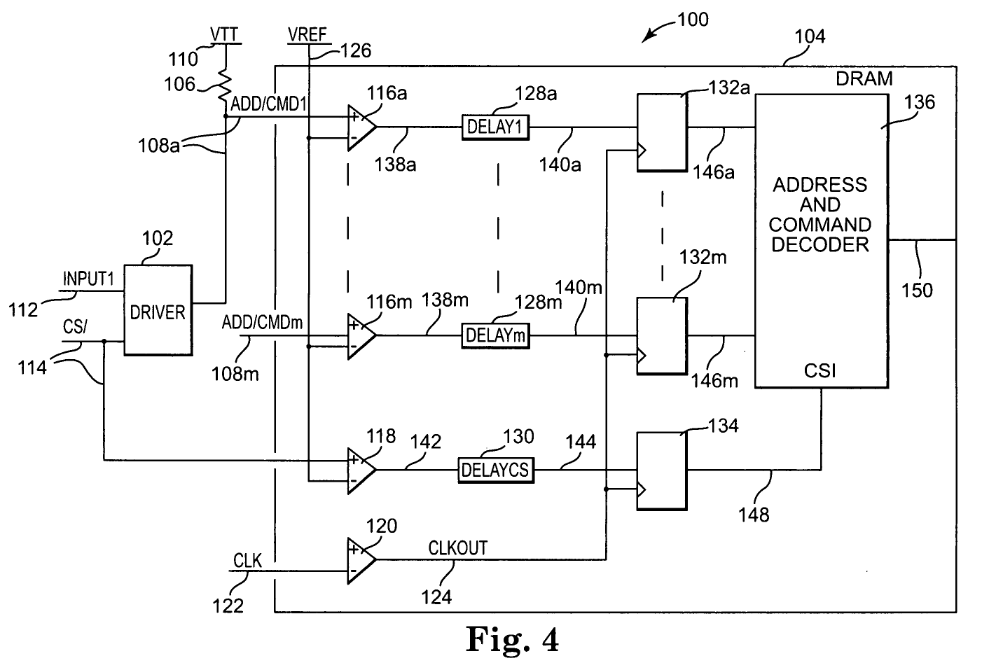

FIG. 4 is a diagram illustrating one embodiment of an electrical system 100 that includes a driver circuit 102, a DRAM 104, and a termination resistor 106. Driver circuit 102 is electrically coupled to DRAM 104 and to one end of termination resistor 106 via signal line 108a. The other end of termination resistor 106 is electrically coupled to termination voltage VTT at 110. Electrical system 100 includes multiple driver circuits (not shown for clarity) that are similar to driver circuit 102 and multiple termination resistors (not shown for clarity) that are similar to termination resistor 106. In one aspect, signal line 108a is a terminated signal line 108a. In one aspect, signal line 108a is a fly by signal line 108a that communicates a fly-by signal to DRAM 104.

Signal line 108a is electrically coupled to other DRAMs (not shown) in electrical system 100. In one embodiment, signal line 108a is electrically coupled to 9 DRAMs. In one embodiment, signal line 108a is electrically coupled to 18 DRAMs. In one embodiment, signal line 108a is electrically coupled to 36 DRAMs. In other embodiments, signal line 108a is electrically coupled to any suitable number of DRAMs.

Driver circuit 102 receives input signal INPUT1 at 112 and chip select signal CS/ at 114. Driver circuit 102 provides first address and command output signal ADD/CMD1 at 108a to DRAM 104 via signal line 108a. Driver circuit 102 provides an output logic level in output signal ADD/CMD1 at 108a at a first drive strength. Then, based on the input signal INPUT1 at 112, the chip select signal CS/ at 114, and/or the output signal ADD/CMD1 at 108a, driver circuit 102 switches and provides the output logic level in output signal ADD/CMD1 at 108a at a second drive strength, wherein the first drive strength is greater than the second drive strength. Switching to the second drive strength saves power in electrical system 100. In one embodiment, the first drive strength is substantially ten times greater than the second drive strength.

DRAM 104 includes address and command input receivers 116a-116m, chip select receiver 118, and clock receiver 120. Clock receiver 120 receives clock signal CLK at 122 and provides clock output signal CLKOUT at 124 in DRAM 104.

Input receivers 116a-116m and chip select receiver 118 are differential input receivers. One input of each of the input receivers 116a-116m and one input of chip select receiver 118 is electrically coupled to a reference signal line 126 that receives reference voltage VREF. The other input of each of the input receivers 116a-116m is electrically coupled to one of the signal lines 108a-108m. The other input of input receiver 116a is electrically coupled to signal line 108a to receive first address and command output signal ADD/CMD1, and so on, up to the other input of input receiver 116m being electrically coupled to signal line 108m to receive address and command output signal ADD/CMDm. The other input of chip select receiver 118 is electrically coupled to chip select line 114.

DRAM 104 includes address and command delay circuits 128a-128m, chip select delay circuit 130, address and command flip-flops 132a-132m, chip select flip-flop 134, and address and command decoder circuit 136. The output of each of the address and command input receivers 116a-116m is electrically coupled to one side of an address and command delay circuit 128a-128m. The output of input receiver 116a is electrically coupled to one side of delay circuit 128a via first output signal line 138a, and so on, up to the output of input receiver 116m being electrically coupled to one side of delay circuit 128m via last output signal line 138m. The other side of each of the address and command delay circuits 128a-128m is electrically coupled to the data input of one of the address and command flip-flops 132a-132m. The other side of address and command delay circuit 128a is electrically coupled to the data input of address and command flip-flop 132a via first delayed signal line 140a, and so on, up to the other side of address and command delay circuit 128m being electrically coupled to the data input of address and command flip-flop 132m via last delayed signal line 140m.

The output of chip select receiver 118 is electrically coupled to one side of the chip select delay circuit 130 via chip select signal line 142. The other side of chip select delay circuit 130 is electrically coupled to the data input of chip select flip-flop 134 via delayed chip select signal line 144. The output of clock receiver 120 is electrically coupled to each of the clock inputs of address and command flip-flops 132a-132m and chip select flip-flop 134 via clock output signal line 124.

The output of each of the address and command flip-flops 132a-132m is electrically coupled to an input of address and command decoder 136. The output of address and command flip-flop 132a is electrically coupled to one input of address and command decoder 136 via first flip-flop output signal line 146a, and so on, up to the output of address and command flip-flop 132m being electrically coupled to another input of address and command decoder 136 via last flip-flop output signal line 146m. The output of chip select flip-flop 134 is electrically coupled to the chip select input of address and command decoder 136 via chip select flip-flop output signal line 148. Address and command decoder provides output signals to read and write DRAM 104 via address and command decoder bus 150.

In electrical system 100, reference voltage VREF at 126 and termination voltage VTT at 110 are substantially equal. In one embodiment, reference voltage VREF at 126 is substantially equal to the power supply voltage of VDD divided by 2 and termination voltage VTT at 110 is substantially equal to the power supply voltage of VDD divided by 2. In other embodiments, reference voltage VREF at 126 and termination voltage VTT at 110 can be any suitable voltage value.

Driver circuits, such as driver circuit 102, receive chip select signal CS/ at 114 and input signals, such as input signal INPUT1 at 112. The driver circuits provide address and command output signals ADD/CMD1-ADD/CMDm at 108a-108m that correspond to the received input signals. Address and command input receivers 116a-116m receive the address and command output signals ADD/CMD1-ADD/CMDm at 108a-108m and provide receiver output signals at 138a-138m to address and command delay circuits 128a128m.

The address and command delay circuits 128a-128m delay the receiver output signals to align the receiver output signals with clock output signal CLKOUT at 124. The delayed receiver output signals are clocked into address and command flip-flops 132a-132m via clock output signal CLKOUT at 124. The outputs of address and command flip-flops 132a-132m are provided to inputs at 146a-146m of address and command decoder 136.

Chip select receiver 118 receives the chip select signal CS/ at 114 and provides a chip select receiver output signal at 142 to chip select delay circuit 130. The chip select delay circuit 130 delays the chip select receiver output signal to align the chip select receiver output signal with clock output signal CLKOUT at 124. The delayed chip select signal is latched into chip select flip-flop 134 via clock output signal CLKOUT at 124 and provided to address and command decoder 136.

If electrical system 100 is selected via a low logic level in chip select signal CS/ at 114, address and command decoder 136 provides read or write signals at 150 to DRAM 104. If electrical system 100 is deselected via a high logic level in chip select signal CS/ at 114, the deselect signal is latched into chip select flip-flop 134 and address and command decoder 136 filters off or ignores the address and command input signals at 146a-146m.

If electrical system 100 was deselected and the driver circuits, such as driver circuit 102, were allowed to continue switching, the address and command output signals ADD/CMD1-ADD/CMDm at 108a-108m would be filtered out via the address and command decoder 136. However, the switching would use power in address and command input receivers 116a-116m, address and command delay circuits 128a-128m, and address and command flip-flops 132a-132m. Also, even if the driver circuits, such as driver circuit 102, were disabled via the deselect signal, the inputs of address and command input receivers 116a-116m would float to reference voltage VREF at 126 and termination voltage VTT at 10. With reference voltage VREF and termination voltage VTT set to the same voltage, the address and command input receivers 116a-116m would randomly switch and power would be used in address and command input receivers 116a-116m, address and command delay circuits 128a-128m, and address and command flip-flops 132a-132m.

In operation of electrical system 100, driver circuit 102 receives input signal INPUT1 at 112 and provides a corresponding address and command output signal ADD/CMD1 at 108a to address and command receiver 116a. Driver circuit 102 outputs an output logic level in output signal ADD/CMD1 at 108a at a first drive strength that drives address and command input receiver 116a to output a corresponding receiver output logic level. After the address and command input receiver 116a has been driven to output the corresponding receiver output logic level via the larger first drive strength, driver circuit 102 switches and provides the output logic level in address and command output signal ADD/CMD1 at 108a at the smaller second drive strength that continues to drive address and command input receiver 116a to output the same corresponding receiver output logic level. The first drive strength is greater than the second drive strength and switching to the second drive strength saves power in electrical system 20.

Driving address and command input receivers, such as address and command input receiver 116a, to output known logic levels reduces the switching of and the power consumed by the address and command input receivers 116a-116m, address and command delay circuits 128a-128m, and address and command flip-flops 132a-132m. Also, since the first drive strength is greater than the second drive strength, switching to the second drive strength saves power in electrical system 100. In one embodiment, the first drive strength is substantially ten times greater than the second drive strength. In one embodiment, the output impedance of driver circuit 102 is 20 ohms at the first drive strength and 200 ohms at the second drive strength. In one embodiment, the output logic level provided via the first drive strength is at least 175 milli-volts (mv) away from the reference voltage VREF at 126. In one embodiment, the output logic level provided via the second drive strength is 100 milli-volts (mv) or less from the reference voltage VREF at 126. In one embodiment, the output logic level provided via the second drive strength is 50 mv or less from the reference voltage VREF at 126. In other embodiments, the first drive strength and the second drive strength can be any suitable drive strengths that provide any suitable logic level output values.

In one embodiment, the output impedance of each of the driver circuits is 20 ohms at the first drive strength and 200 ohms at the second drive strength. Also, termination resistors, such as termination resistor 106, have a resistance value of 36 ohms and termination voltage VTT at 110 is 0.75 volts. If the driver circuits output a low logic level of 0 volts at the first drive strength of 20 ohms, the current consumed in each signal line is equal to 0.75 volts divided by 56 ohms or substantially 13.4 milli-amperes (mA) per signal line. The output logic level provide via this first drive strength is 428 milli-volts (mV) from a reference voltage VREF at 126 of 0.75 volts. Also, if 44 lines are driven, the total current consumed is substantially 590 mA.

After driver circuits switch to provide the second drive strength of 200 ohms and a low logic level of 0 volts, the current consumed in each signal line is equal to 0.75 volts divided by 236 ohms or substantially 3.2 mA per signal line. The output logic level provide via this second drive strength is 114 milli-volts from the reference voltage VREF at 126 of 0.75 volts. Also, if 44 lines are driven, the total current consumed is 140 mA, which is about 450 mA less than the current consumed while the driver circuits are at the first drive strength. In other embodiments, the second drive strength can be reduced further to save more power, while still driving the address and command receivers to the corresponding receiver output logic level.

Driver circuit 102 switches from providing an output at the first drive strength to providing the output at the second drive strength based on one or more of the following: input signal INPUT1 at 112, output signal ADD/CMD1 at 108a, and select signal CS/ at 114. In one embodiment, driver circuit 102 switches and outputs the logic level at the second drive strength based on reaching a signal level in the output signal ADD/CMD1 at 108a.

In one embodiment, if electrical system 100 is deselected via chip select signal CS/ at 114, each of the driver circuits, including driver circuit 102, provides a low logic level in the corresponding address and command output signal ADD/CMD1-ADD/CMDm at 108a-108m. The driver circuits output the low logic levels at the first drive strength that drives address and command input receivers 116a-116m to output low receiver output logic levels. Based on the high logic level of chip select signal CS/ at 114, the driver circuits switch and provide the low logic levels in the address and command output signals ADD/CMD1-ADD/CMDm at 108a-108m at a second drive strength that continues to drive address and command input receivers 116a-116m to output the low receiver output logic levels.

In one embodiment, if electrical system 100 is deselected via chip select signal CS/ at 114, driver circuit 102 switches to the second drive strength following a time delay after chip select signal CS/ at 114 transitions to a high logic level. The time delay can be a fraction of a clock cycle or one or more clock cycles. In one embodiment, if electrical system 100 is deselected via chip select signal CS/ at 114, driver circuit 102 switches to the second drive strength in response to the output signal ADD/CMD1 at 108a reaching a signal level value. In one embodiment, if electrical system 100 is deselected via chip select signal CS/ at 114, driver circuit 102 switches to the second drive strength following a combination of a time delay from chip select signal CS/ at 114 transitioning to a high logic level and the output signal ADD/CMD1 at 108a reaching a signal level value.

In one embodiment, driver circuits, such as driver circuit 102, switch to the second drive strength based on input signals, such as input signal INPUT1 at 112, remaining at one input logic level, i.e., not transitioning. If input signal INPUT1 at 112 does not transition, driver circuit 102 provides a low logic level in the corresponding address and command output signal ADD/CMD1 at 108a. Driver circuit 102 outputs the low logic level at the first drive strength that drives address and command input receiver 116a to output a low receiver output logic level. In response to the lack of a transition, driver circuit 102 switches and provides the low logic level in the address and command output signal ADD/CMD1 at 108a at a second drive strength that continues to drive address and command input receivers 116a to output the low receiver output logic level.

In one embodiment, if input signal INPUT1 at 112 does not transition, driver circuit 102 switches to the second drive strength following a time delay after the last transition of input signal INPUT1 at 112. The time delay can be a fraction of a clock cycle or one or more clock cycles. In one embodiment, if input signal INPUT1 at 112 does not transition, driver circuit 102 switches to the second drive strength in response to the output signal ADD/CMD1 at 108a reaching a signal level value. In one embodiment, if input signal INPUT1 at 112 does not transition, driver circuit 102 switches to the second drive strength following a combination of a time delay after the last transition of input signal INPUT1 at 112 and the output signal ADD/CMD1 at 108a reaching a signal level value.

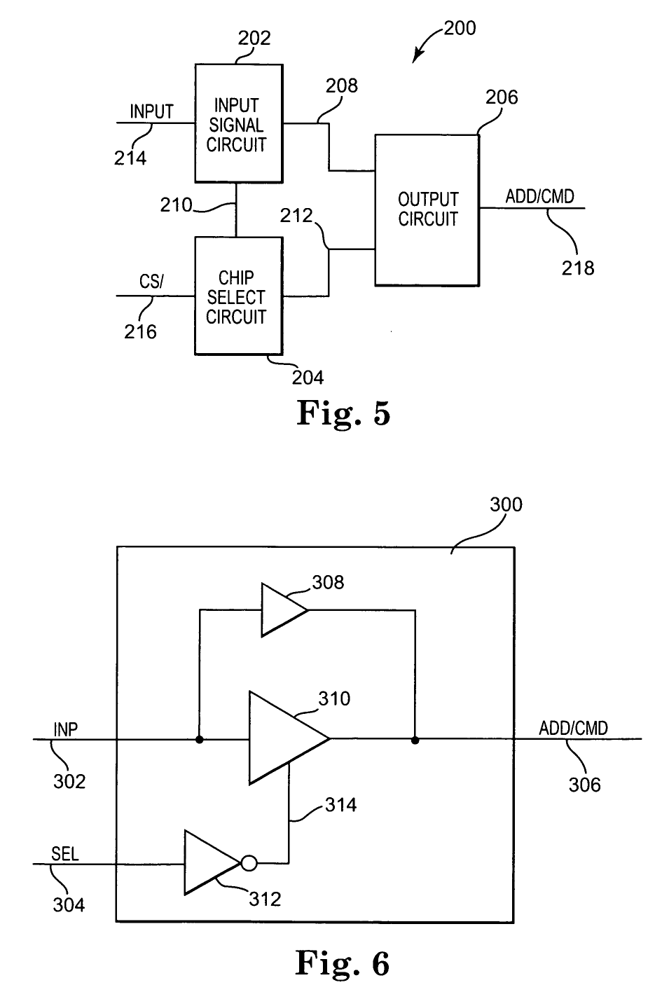

FIG. 5 is a diagram illustrating one embodiment of a driver circuit 200 that includes an input signal circuit 202, a chip select circuit 204, and an output circuit 206. Input signal circuit 202 is electrically coupled to output circuit 206 via input communications path 208 and to chip select circuit 204 via input select communications path 210. Chip select circuit 204 is electrically coupled to output circuit 206 via output select communications path 212.

Input signal circuit 202 receives input signal INPUT at 214 and chip select circuit 204 receives chip select signal CS/ at 216. Output circuit 206 outputs the address and command output signal ADD/CMD at 218. In one embodiment, each of the circuits including input signal circuit 202, chip select circuit 204, and output circuit 206 receives a clock signal.

In operation, chip select circuit 204 receives a low logic level in chip select signal CS/ at 216, which selects driver circuit 200. In response to the low logic level in chip select signal CS/ at 216, chip select circuit 204 provides an input select signal to input signal circuit 202 via input select communications path 210 and an output select signal to output circuit 206 via output select communications path 212. Based on receiving the input select signal, input signal circuit 202 receives input signal INPUT at 214 and provides a corresponding input signal to output circuit 206 via input communications path 208. Output circuit 206 outputs an address and command output signal ADD/CMD at 218 that corresponds to input signal INPUT at 214 that was received via input signal circuit 202.

In one embodiment, output circuit 206 outputs a logic level in address and command output signal ADD/CMD at 218 at a first drive strength and then switches to the second drive strength based on input signal INPUT at 214 remaining at one input logic level, i.e., not transitioning. Output circuit 206 outputs the logic level at the first drive strength that drives an input receiver, such as address and command input receiver 116a, to output a receiver output logic level. In response to the lack of a transition, output circuit 102 switches and provides the logic level in the address and command output signal ADD/CMD at 218 at the second drive strength that continues to drive the input receiver to the same receiver output logic level.

In one embodiment, if input signal INPUT at 214 does not transition, output circuit 206 switches to the second drive strength following a time delay after the last transition of input signal INPUT at 214. The time delay can be a fraction of a clock cycle or one or more clock cycles. In one embodiment, expiration of the time delay is determined via output circuit 206. In one embodiment, expiration of the time delay is determined via input signal circuit 202, which signals output circuit 206 that the time delay has elapsed.

In one embodiment, if input signal INPUT at 214 does not transition, output circuit 206 switches to the second drive strength in response to the output signal ADD/CMD at 218 reaching a signal level value. In one embodiment, output circuit 206 determines whether output signal ADD/CMD at 218 has reached the signal level value. In one embodiment, if input signal INPUT at 214 does not transition, output circuit 206 switches to the second drive strength following a combination of a time delay after the last transition of input signal INPUT at 214 and output signal ADD/CMD at 218 reaching a signal level value.

In another operation, chip select circuit 204 receives a high logic level in chip select signal CS/ at 216, which deselects driver circuit 200. Chip select circuit 204 provides an input deselect signal to input signal circuit 202 via input select communications path 210 and an output deselect signal to output circuit 206 via output select communications path 212. Based on the input deselect signal, input signal circuit 202 provides a low logic level input signal to output circuit 206 via input communications path 208. Output circuit 206 outputs a low logic level in address and command output signal ADD/CMD at 218.

In one embodiment, output circuit 206 provides the low logic level in address and command output signal ADD/CMD at 218 at a first drive strength that drives an input receiver to output a low receiver output logic level. Based on the output deselect signal, output circuit 206 switches and provides the low logic level in address and command output signal ADD/CMD at 218 at a second drive strength that continues to drive the input receiver to output the low receiver output logic level.

In one embodiment, if driver circuit 200 is deselected via chip select signal CS/ at 216, output circuit 206 switches to the second drive strength following a time delay after chip select signal CS/ at 216 transitions to a high logic level. The time delay can be a fraction of a clock cycle or one or more clock cycles. In one embodiment, chip select circuit 204 delays the output select signal to delay switching to the second drive strength. In one embodiment, output circuit 206 delays the output select signal to delay switching to the second drive strength.

In one embodiment, if driver circuit 200 is deselected via chip select signal CS/ at 216, output circuit 206 switches to the second drive strength in response to the output signal ADD/CMD at 218 reaching a signal level value. In one embodiment, output circuit 206 determines whether output signal ADD/CMD at 218 has reached the signal level value. In one embodiment, if driver circuit 200 is deselected via chip select signal CS/ at 216, output circuit 206 switches to the second drive strength following a combination of a time delay from chip select signal CS/ at 216 transitioning to a high logic level and the output signal ADD/CMD at 218 attaining a signal level value.

FIG. 6 is a diagram illustrating one embodiment of an output circuit 300. Output circuit 300 receives input signal INP at 302 and select signal SEL at 304 and outputs address and command signal ADD/CMD at 306. In one embodiment, output circuit 300 is similar to output circuit 206 (shown in FIG. 5).

Output circuit 300 includes a first output buffer 308, a second output buffer 310, and an inverter 312. The input of first output buffer 308 is electrically coupled to the input of second output buffer 310 via input signal line 302. The output of first output buffer 308 is electrically coupled to the output of second output buffer 310 via output signal line 306. The input of inverter 312 is electrically coupled to select signal line 304 and the output of inverter 312 is electrically coupled to the enable input of second output buffer 310 via enable signal line 314. If select signal SEL at 304 is at a high logic level, second output buffer 310 is disabled and does not drive address and command output signal ADD/CMD at 306. If select signal SEL at 304 is at a low logic level, second output buffer 310 is enabled to drive address and command output signal ADD/CMD at 306.

First output buffer 308 provides less output drive than second output buffer 310. In one embodiment, first output buffer 308 provides substantially one tenth of the first drive strength and second output buffer 310 provides substantially nine tenths of the first drive strength. In other embodiments, first output buffer 308 provides any suitable portion of first drive strength and second output buffer 310 provides any suitable portion of the first drive strength.

In operation, if select signal SEL at 304 is at a low logic level, second output buffer 310 is enabled to drive address and command output signal ADD/CMD at 306. First output buffer 308 and second output buffer 310 receive input signal INP at 302 and provide the corresponding logic level at the first drive strength in address and command signal ADD/CMD at 306. As select signal SEL at 304 transitions to a high logic level, second output buffer 310 is disabled and first output buffer 308 drives the logic level at the second drive strength in address and command signal ADD/CMD at 306.

In one embodiment, output circuit 300 includes analog and/or digital logic circuitry to delay a high logic level in select signal SEL at 302 and provide the first drive strength for a time delay and thereafter provide the second drive strength in address and command output signal ADD/CMD at 306. In one embodiment, output circuit 300 includes analog and/or digital logic circuitry to detect that address and command output signal ADD/CMD at 306 has attained a signal level value and to disable second output buffer 310 once the signal level is attained. In one embodiment, output circuit 300 includes analog and/or digital logic circuitry to delay a high logic level in select signal SEL at 302 and detect that address and command output signal ADD/CMD at 306 has attained a signal level value and provide the first drive strength for a time and thereafter provide the second drive strength in address and command output signal ADD/CMD at 306.

In other embodiments, output circuit 300 includes analog and/or digital logic circuitry to detect a transition in input signal INP at 302 and switch to provide address and command output signal ADD/CMD at 306 at the second drive strength based on the transition. In other embodiments, output circuit 300 includes analog and/or digital logic circuitry to detect a transition in input signal INP at 302 and switch to provide address and command output signal ADD/CMD at 306 at the second drive strength based on the detected transition and one of a time delay from the transition, attaining a signal level in address and command output signal ADD/CMD at 306, or a combination of a time delay and attaining a signal level in address and command output signal ADD/CMD at 306.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An electrical system, comprising:
a signal line that is terminated via a passive component; and
a driver configured to receive an input signal and provide an output signal via the signal line and to provide an output logic level in the output signal at a first drive strength and to switch and provide the output logic level in the output signal at a second drive strength, wherein the first drive strength is greater than the second drive strength.

2. The electrical system of claim 1, wherein the driver is configured to switch and provide the output logic level in the output signal at the second drive strength based on de-selection of a circuit that is configured to receive the output signal.

3. The electrical system of claim 1, wherein the driver is configured to switch and provide the output logic level in the output signal at the second drive strength based on the input signal remaining at an input logic level.

4. The electrical system of claim 1, wherein the driver is configured to switch and provide the output logic level in the output signal at the second drive strength based on a signal level of the output signal.

5. The electrical system of claim 1, wherein the driver is configured to switch and provide the output logic level in the output signal at the second drive strength based on time from a transition of the input signal.

6. The electrical system of claim 1, wherein the driver is configured to switch and provide the output logic level in the output signal at the second drive strength based on a combination of a signal level of the output signal and time from a transition of the input signal.

7. The electrical system of claim 1, wherein the first drive strength is at least ten times greater than the second drive strength.

8. A memory system, comprising:
memory circuits including receivers configured to receive fly-by signals;
a bus that is terminated via at least one passive component and configured to communicate the fly-by signals to the receivers in the memory circuits; and
drivers configured to provide the fly-by signals to the receivers in the memory circuits via the bus, wherein each of the drivers is configured to provide a fly-by output signal at a first signal level to establish multiple receivers of the receivers at a logic level and to provide the fly-by output signal at a second signal level to maintain the multiple receivers at the logic level and save power in the memory system.

9. The memory system of claim 8, wherein the first signal level is at least 175 milli-volts from a reference value.

10. The memory system of claim 8, wherein the second signal level is less than 175 milli-volts from a reference value.

11. The memory system of claim 8, wherein the second signal level is less than 100 milli-volts from a reference value.

12. The memory system of claim 8, wherein the memory circuits are dynamic random access memory circuits that are part of a registered dual in-line memory module.

13. The memory system of claim 8, wherein the memory circuits are dynamic random access memory circuits that are part of a fully buffered dual in-line memory module.

14. An electrical system, comprising:
means for receiving an input signal;
means for communicating an output signal that corresponds to the input signal;
means for providing an output logic level in the output signal at a first drive strength; and
means for switching to provide the output logic level in the output signal at a second drive strength that is less than the first drive strength.

15. The electrical system of claim 14, wherein the means for switching comprises means for switching to provide the output logic level in the output signal at the second drive strength based on de-selection of a circuit that is configured to receive the output signal.

16. The electrical system of claim 14, wherein the means for switching comprises means for switching to provide the output logic level in the output signal at the second drive strength based on the input signal remaining at an input logic level.

17. The electrical system of claim 14, wherein the means for switching comprises means for switching to provide the output logic level in the output signal at the second drive strength based on a signal level of the output signal.

18. The electrical system of claim 14, wherein the means for switching comprises means for switching to provide the output logic level in the output signal at the second drive strength based on time from a transition of the input signal.

19. The electrical system of claim 14, wherein the means for switching comprises means for switching to provide the output logic level in the output signal at the second drive strength based on a combination of a signal level of the output signal and time from a transition of the input signal.

20. A method of driving an output signal on a terminated signal line, comprising:
receiving an input signal;
communicating the output signal that corresponds to the input signal;
providing an output logic level in the output signal at a first drive strength; and
switching to provide the output logic level in the output signal at a second drive strength that is less than the first drive strength.

21. The method of claim 20, wherein switching comprises:
switching to provide the output logic level in the output signal at the second drive strength based on de-selection of a circuit that is configured to receive the output signal.

22. The method of claim 20, wherein switching comprises:
switching to provide the output logic level in the output signal at the second drive strength based on the input signal remaining at an input logic level.

23. The method of claim 20, wherein switching comprises:
switching to provide the output logic level in the output signal at the second drive strength based on a signal level of the output signal.

24. The method of claim 20, wherein switching comprises:
switching to provide the output logic level in the output signal at the second drive strength based on time from a transition of the input signal.

25. A method of driving fly-by signals on a terminated bus to receivers in memory circuits, comprising:
receiving fly-by signals at the receivers;
communicating the fly-by signals to the receivers via the terminated bus; and
providing a fly-by output signal at a first signal level to establish multiple receivers of the receivers at a logic level; and
providing the fly-by output signal at a second signal level that maintains the multiple receivers at the logic level and saves power.

26. The method of claim 25, wherein providing a fly-by output signal at a first signal level comprises:
providing the fly-by output signal at the first signal level of at least 175 milli-volts from a reference value.

27. The method of claim 25, wherein providing the fly-by output signal at a second signal level comprises:
providing the fly-by output signal at the second signal level of less than 175 milli-volts from a reference value.

28. The method of claim 25, wherein providing the fly-by output signal at a second signal level comprises:
providing the fly-by output signal at the second signal level of less than 100 milli-volts from a reference value.
